(19) United States
(12) Patent Application Publication
(10) Pub. No.: US 2020/0252072 A1
(43) Pub. Date: Aug. 6, 2020

(54) CLOCK AND DATA RECOVERY CIRCUIT, MEMORY STORAGE DEVICE AND FLASH MEMORY CONTROLLER

(71) Applicant: PHISON ELECTRONICS CORP., Miaoli (TW)

(72) Inventor: Jen-Chu Wu, New Taipei City (TW)

(73) Assignee: PHISON ELECTRONICS CORP., Miaoli (TW)

(21) Appl. No.: 16/373,653

(22) Filed: Apr. 3, 2019

(30) Foreign Application Priority Data
Feb. 1, 2019 (TW) 108104038

(51) Int. Cl. H03L 7/199; H03L 7/07; H03L 7/08; H03L 7/081; H03L 7/091; G11C 7/22

(52) U.S. Cl. CPC H03L 7/199; H03L 7/07; G11C 7/22; H03L 7/0814; H03L 7/091; H03L 7/0802

(57) ABSTRACT

A clock and data recovery circuit which includes a phase detector, a digital loop filter and a phase interpolator is provided according to an exemplary embodiment of the disclosure. The phase detector is configured to detect a phase difference between a data signal and a clock signal. The phase interpolator is configured to generate the clock signal according to an output of the digital loop filter. The digital loop filter is configured to operate automatically according a default value stored in the digital loop filter under an initial status, so as to establish a default phase shift or a default frequency difference of the clock signal with respect to the data signal before the data signal and the clock signal are compared.

### CROSS-REFERENCE TO RELATED APPLICATION

This application claims the priority benefit of Taiwan application serial no. 108104038, filed on Feb. 1, 2019. The entirety of the above-mentioned patent application is hereby incorporated by reference herein and made a part of this specification.

### BACKGROUND

### Technical Field

The disclosure relates to an electronic circuit technology, and more particularly to a clock and data recovery circuit, a memory storage device, and a flash memory controller.

### Description of Related Art

Along with the widespread of digital cameras, cell phones, and MP3 in recent years, the consumers' demand for storage media has increased drastically. Rewritable non-volatile memory module (e.g., flash memory) is highly suitable for being embedded in the various portable multi-media devices listed above due to its characteristics such as data non-volatility, low power consumption, small volume, and non-mechanical structure.

The clock and data recovery circuit is provided in most electronic devices to perform clock correction as necessary. However, in some cases, if there is a clock skew in the clock signal, since the phase of the initially generated clock signal is in the detection dead zone, it is likely that the phase detector in the clock and data recovery circuit cannot smoothly provide the corresponding clock adjusting signal. If the clock signal cannot leave the detection dead zone after a period of preset time, it is likely to cause error in the analysis of data signal.

### SUMMARY

The disclosure provides a clock and data recovery circuit, a memory storage device and a flash memory controller, which can improve the above problems.

An exemplary embodiment of the disclosure provides a clock and data recovery circuit including a phase detector, a digital loop filter, and a phase interpolator. The phase detector is configured to detect a phase difference between the data signal and the clock signal. The digital loop filter is coupled to the phase detector. The phase interpolator is coupled to the phase detector and the digital loop filter and configured to generate the clock signal according to an output of the digital loop filter. The digital loop filter is configured to automatically operate according to a default value stored in the digital loop filter under an initial state to establish a default phase shift or a default frequency difference of the clock signal with respect to the data signal before the data signal and the clock signal are compared.

An exemplary embodiment of the disclosure further provides a memory storage device including a connection interface unit, a rewritable non-volatile memory module, a memory control circuit unit and a clock and data recovery circuit. The connection interface unit is configured to be coupled to a host system. The memory control circuit unit is coupled to the connection interface unit and the rewritable non-volatile memory module. The clock and data recovery circuit is disposed in at least one of the connection interface unit and the memory control circuit unit. The clock and data recovery circuit is configured to receive a data signal, generate a clock signal, and detect a phase difference between the data signal and the clock signal. The clock and data recovery circuit is further configured to automatically operate according to a default value stored in the clock and data recovery circuit under an initial state to establish a default phase shift or a default frequency difference of the clock signal with respect to the data signal before the data signal and the clock signal are compared.

An exemplary embodiment of the disclosure further provides a flash memory controller for controlling a rewritable non-volatile memory module. The flash memory controller includes a clock and data recovery circuit. The clock and data recovery circuit is configured to receive a data signal, generate a clock signal, and detect a phase difference between the data signal and the clock signal. The clock and data recovery circuit is further configured to automatically operate according to a default value stored in the clock and data recovery circuit under an initial state to establish a default phase shift or a default frequency difference of the clock signal with respect to the data signal before the data signal and the clock signal are compared.

In an exemplary embodiment of the disclosure, the default value is not provided by the phase detector.

In an exemplary embodiment of the disclosure, the default value is independent of the phase difference.

In an exemplary embodiment of the disclosure, the clock and data recovery circuit includes a phase detector, a digital loop filter, and a phase interpolator. The digital loop filter includes at least one amplifier and at least one accumulator. The amplifier is coupled to an output terminal of the phase detector. The accumulator is coupled to an output terminal of the amplifier and an input terminal of the phase interpolator. The default value is burned in the accumulator.

In an exemplary embodiment of the disclosure, the amplifier includes a first amplifier and a second amplifier. The accumulator includes a first accumulator and a second accumulator. An input terminal of the first amplifier and an input terminal of the second amplifier are coupled to the output terminal of the phase detector. An input terminal of the first accumulator is coupled to an output terminal of the second amplifier. An input terminal of the second accumulator is coupled to an output terminal of the first amplifier and an output terminal of the first accumulator. An output terminal of the second accumulator is coupled to the phase interpolator.

In an exemplary embodiment of the disclosure, the default value is burned in the first accumulator.

In an exemplary embodiment of the disclosure, the default value is an integer, and the default value is not zero.

Based on the above, a default value may be pre-stored in the clock and data recovery circuit, and the default value is used to establish a default phase shift or a default frequency difference of the clock signal with respect to the data signal before the data signal and the clock signal are compared. In some cases, if the phase (or sampling point) of the clock signal is in the detection dead zone, the default phase shift or default frequency difference helps to quickly drive the clock signal away from the detection dead zone, thereby effectively increasing the operation efficiency of the clock and data recovery circuit.

In order to make the aforementioned features and advantages of the disclosure more comprehensible, embodiments accompanying figures are described in detail below.

### BRIEF DESCRIPTION OF THE DRAWINGS

FIG. 1 is a schematic diagram of a clock and data recovery circuit according to an exemplary embodiment of the disclosure.

FIG. 2 is a schematic diagram showing a phase relationship between signals according to an exemplary embodiment of the disclosure.

FIG. 3 is a schematic diagram of a digital loop filter according to an exemplary embodiment of the disclosure.

FIG. 4 is a schematic diagram of a host system, a memory storage device, and an input/output (I/O) device according to an exemplary embodiment of the disclosure.

FIG. 5 is a schematic diagram of a host system, a memory storage device, and an I/O device according to another exemplary embodiment of the disclosure.

FIG. 6 is a schematic diagram of a host system and a memory storage device according to another exemplary embodiment of the disclosure.

FIG. 7 is a schematic block diagram of a memory storage device according to an exemplary embodiment of the disclosure.

### DESCRIPTION OF EMBODIMENTS

Several embodiments of the disclosure are introduced below to describe the disclosure; however the disclosure is not limited by the embodiments. Suitable combinations among the embodiments are also allowed. The term “coupled to” used throughout the embodiments (including claims) may refer to any direct and indirect connection means. For example, if a first device is described as being coupled to a second device in the embodiments, the sentence should be interpreted as the first device may be connected to the second device directly, or the first device may, through any other device or through certain connection means, be connected to the second device indirectly. In addition, the word “signal” may refer to at least one current, voltage, electric charge, temperature, data, or any other one or more signals.

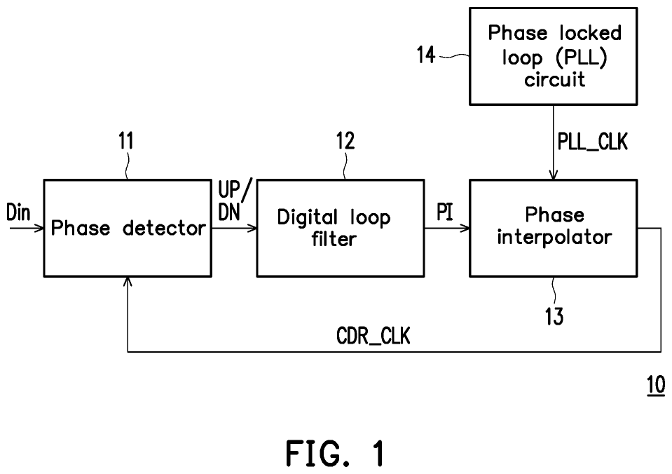

FIG. 1 is a schematic diagram of a clock and data recovery circuit according to an exemplary embodiment of the disclosure. Referring to FIG. 1, a clock and data recovery circuit 10 can be used to receive a signal Din and generate a signal CDR_CLK. The clock and data recovery circuit 10 can also detect a phase difference between the signal Din and the signal CDR_CLK and adjust the signal CDR_CLK according to the phase difference. For example, the clock and data recovery circuit 10 can adjust the phase and/or frequency of the signal CDR_CLK according to the phase and/or frequency of the signal Din. In this manner, the clock and data recovery circuit 10 can be used to lock the signal Din and the signal CDR_CLK in a default phase relationship. For example, the phase difference between signal Din and the signal CDR_CLK can be locked at 90 degrees, 180 degrees, 270 degrees, or 360 degrees. The locked signal CDR_CLK can be used to analyze (e.g., sample) the signal Din to obtain the bit data (e.g., bit 1/0) transmitted by the signal Din. In an exemplary embodiment, the signal Din is also referred to as a data signal and/or the signal CDR_CLK is also referred to as a clock signal.

The clock and data recovery circuit 10 includes a phase detector 11, a digital loop filter 12, and a phase interpolator 13. The phase detector 11 can be used to receive the signal Din and the signal CDR_CLK and detect the phase difference between the signal Din and the signal CDR_CLK. The phase detector 11 can output the signal UP/DN according to the phase difference. The signal UP/DN can be used to change the phase and/or frequency of the signal CDR_CLK. For example, the signal UP can be used for advancing at least one rising edge and/or at least one falling edge of the signal CDR_CLK. The signal DN can be used to delay at least one rising edge and/or at least one falling edge of the signal CDR_CLK. In an exemplary embodiment, the signal UP/DN is also referred to as a correction signal.

The digital loop filter 12 is coupled to the phase detector 11. The digital loop filter 12 is used to receive the signal UP/DN and generate a signal PI according to the signal UP/DN. The signal PI may correspond to a code (or control code). This code (or control code) can be used to control the phase and/or frequency of the signal CDR_CLK. In an exemplary embodiment, the signal PI is also referred to as a phase control signal.

The phase interpolator 13 is coupled to the digital loop filter 12 and the phase detector 11. The phase interpolator 13 is configured to receive the signal PI and the signal PLL_CLK. The phase interpolator 13 can perform phase interpolation on the signal PLL_CLK according to the signal PI to generate the signal CDR_CLK. For example, the phase interpolator 13 can adjust the phase and/or frequency of the signal CDR_CLK according to the signal PI. The signal PLL_CLK may be provided by a phase locked loop (PLL) circuit 14. The PLL circuit 14 may be included in the clock and data recovery circuit 10 or may be independent of the clock and data recovery circuit 10, and the disclosure provides no limitation. Through the operation of the phase detector 11, the digital loop filter 12 and the phase interpolator 13, the signal Din and the signal CDR_CLK can be locked in the default phase relationship to facilitate subsequent signal analysis. In addition, the signal CDR_CLK may also be provided to other circuit components for use.

In an exemplary embodiment, the phase detector 11 can be a half-rate phase detector or a quarter rate phase detector. Therefore, in operation, the phase detector 11 may not work properly for some reason (for example, the sampling point of the signal CDR_CLK is located in the detection dead zone), for example, the signal UP/DN cannot be generated properly.

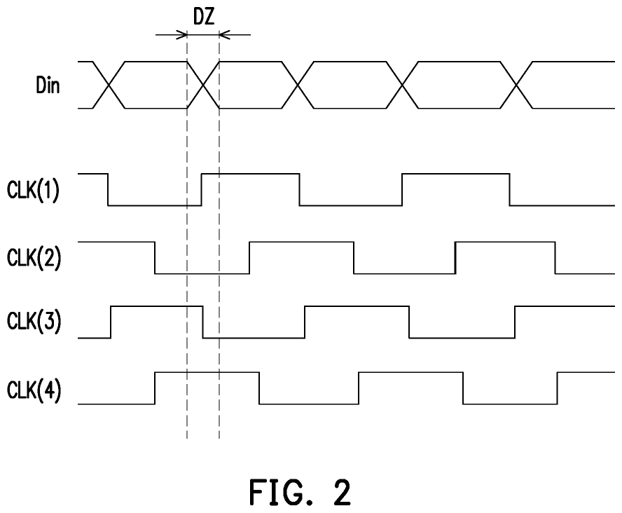

FIG. 2 is a schematic diagram showing a phase relationship between signals according to an exemplary embodiment of the disclosure. Referring to FIG. 1 and FIG. 2, it is assumed that the signal CDR_CLK includes four signals CLK(1)˜CLK(4). In an ideal state, the signals CLK(1)˜CLK(4) have the same frequency and a phase difference between the signals CLK(1)˜CLK(4) is 90 degrees. For example, the signal CLK(1) is inverted from the signal CLK(3), the signal CLK(2) is inverted from the signal CLK(4), and a phase difference between the signal CLK(1) and the signal CLK(2) is 90 degrees. In addition, in an ideal state, the clock and data recovery circuit 10 can lock the phase difference between the signal CKL(1) and the signal Din to 90 degrees by adjusting the phases of the signals CLK(1) to CLK(4) to facilitate subsequent analysis (e.g., sampling) of the signal Din.

However, in an exemplary embodiment, if there is a clock skew between the signals CLK(1)˜CLK(4), the clock and data recovery circuit 10 might not accurately correct the signals CLK(1)˜CLK. For example, if there is a clock skew between the signals CLK(1)˜CLK(4), there might be a detection dead zone DZ at the boundary between any two pointsof the signal Din. If the rising edge or falling edge of any of the signals CLK(1) to CLK(4) is within the detection dead zone DZ, the clock and data recovery circuit 10 might not accurately correct the signal or might not generate a correction signal accordingly. For example, if at least one sampling point of the signal CLK(1) is located at the rising edge or the falling edge of the signal Din and/or at least one sampling point of the signal CLK(3) is located at the rising edge or the falling edge of the signal Din, it is likely that clock skew might occur and sampling error might be caused, which in turn causes the phase detector 11 to fail generating the signal UP/DN smoothly. If the signal UP/DN cannot be generated, the signal CDR_CLK may not be corrected.

In other words, in an exemplary embodiment, if there is a clock skew between the signals CLK(1)˜CLK(4), the phase detector 11 might not smoothly generate the signal UP/DN to assist the signals CLK(1)˜CLK(4) in leaving the detection dead zone DZ. In addition, in an exemplary embodiment, the detection dead zone DZ may be other locations located in the signal Din, the disclosure provides no limitation thereto.

In an exemplary embodiment, a default value might be stored in the clock and data recovery circuit 10 (e.g., digital loop filter 12). This default value is not provided by the phase detector 11. This default value is also independent of the phase difference detected by the phase detector 11. In addition, this default value can be a positive integer or a negative integer, and this default value is not zero.

In the initial state (for example, when the signal CDR_CLK begins to be corrected), if the phase (or sampling point) of the signal CDR_CLK (for example, at least one of the signals CLK(1) to CLK(4)) is in the detection dead zone DZ, the digital loop filter 12 may generate a corresponding signal PI according to the default value. According to this signal PI, the phase interpolator 13 can establish a default phase shift or a default frequency difference of the signal CDR_CLK with respect to the signal Din between the signal Din and the signal CDR_CLK which have not been compared by the phase detector 11. This default phase shift or the default frequency difference is controlled by this default value. With the default phase shift or the default frequency difference, the clock and data recovery circuit 10 can quickly drive the signal CDR_CLK away from the detection dead zone DZ. After the signal CDR_CLK leaves the detection dead zone DZ, the signal Din and the signal CDR_CLK can be locked in the correct phase relationship by the continuous operation between the phase detector 11, the digital loop filter 12 and the phase interpolator 13.

From another point of view, by pre-storing the default value in the clock and data recovery circuit 10 (for example, the digital loop filter 12), it is possible to reduce the problem occurring to the clock and data recovery circuit 10, namely the signal CDR_CLK cannot leave the detection dead zone DZ due to clock skew (or it requires a long correction process in order to leave), thereby improving the operation efficiency of the clock and data recovery circuit 10.

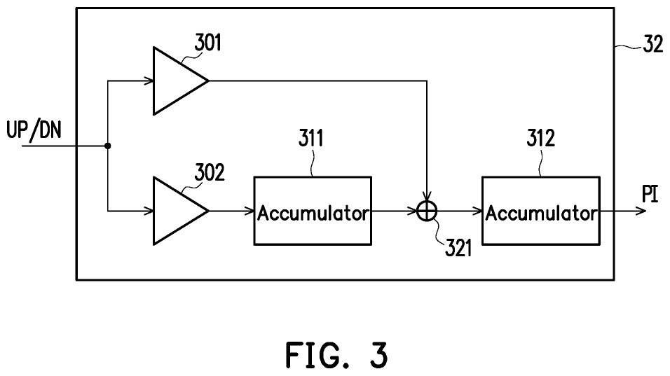

FIG. 3 is a schematic diagram of a digital loop filter according to an exemplary embodiment of the disclosure. Referring to FIG. 1 and FIG. 3, a digital loop filter 32 can be the same or similar to the digital loop filter 12. The digital loop filter 32 includes an amplifier (also referred to as a first amplifier) 301, an amplifier (also referred to as a second amplifier) 302, an accumulator (also referred to as a first accumulator) 311, an accumulator (also referred to as a second accumulator) 312 and an adder 321.

In the exemplary embodiment, the input terminals of the amplifiers 301 and 302 can be coupled to the output terminal of the phase detector 11 to receive the signal UP/DN. An input terminal of the accumulator 311 can be coupled to an output terminal of the amplifier 302. The output terminals of the accumulator 311 and the amplifier 301 can be coupled to the input terminal of the adder 321. The input terminal of the accumulator 312 can be coupled to the output terminal of the adder 321. The output terminal of the accumulator 312 can be coupled to the input terminal of the phase interpolator 13 to provide the signal PI to the phase interpolator 13.

In the exemplary embodiment, the amplifier 301 is also referred to as a proportional gain amplifier, and the amplifier 302 is also referred to as an integral gain amplifier. For example, the amplifier 301 can amplify the value corresponding to the signal UP/DN by N times, and the amplifier 302 can amplify the value corresponding to the signal UP/DN by M times. N is greater than M. For example, N may be 6 and/or M may be 4, and the values of N and M are not limited thereto. The value magnified by the amplifier 302 by M times can be used to update the value stored by the accumulator 311. The adder 321 can add the value stored in the accumulator 311 to the value outputted from the amplifier 301 and update the value stored in the accumulator 312 according to the calculation result. Then, the signal PI can be generated based on the value stored in the accumulator 312.

In the exemplary embodiment, the default value may be stored in the accumulator 311 in advance. For example, this default value can be burned in the accumulator 311 as an initial value of the accumulator 311. This default value is a non-zero integer (which can be a positive integer or a negative integer), so the initial value of the accumulator 311 is also a non-zero integer (which can be a positive integer or a negative integer).

In an exemplary embodiment, it is assumed that the default value is “1” (i.e., the initial value of the accumulator 311 is “1”), N is 6, and M is 4. After the clock and data recovery circuit 10 is activated, in response to a signal UP (e.g., corresponding to the value “1”), the value stored by the accumulator 311 can be updated to “5” (e.g., 4+1=5), and the value stored by the accumulator 312 can be updated to “11” (e.g., 6+5=11). Therefore, corresponding to the value (for example, “11”) stored by the accumulator 312, the corresponding signal PI can be outputted. Then, in response to a signal DN (corresponding to the value “−1”), the value stored by the accumulator 311 can be updated to “1” (5+(−4)=1), and the value stored by the accumulator 312 can be updated to “6” ((−6)+1+11=6). Therefore, corresponding to the value (for example, “6”) stored by the accumulator 312, the corresponding signal PI can be outputted, and so forth. In response to the inputted signal UP/DN, the values stored by the accumulators 311 and 312 can be continuously updated and the corresponding signal PI can be continuously outputted.

Typically, the initial value of the accumulator 311 might not be preset and/or the initial value of the accumulator 311 is set to zero. Therefore, due to the detection dead zone DZ, the phase detector 11 might not be able to provide the signal UP/DN, thereby causing the signal CDR_CLK to be unable to leave (or it requires a long correction process in order to leave) the detection dead zone DZ. However, in the exemplary embodiment, the initial value of the accumulator 311 is preset as a non-zero integer. Therefore, even if the phase detector 11 is affected by the detection dead zone DZ and cannot provide the signal UP/DN, an initial signal PI can be generated in response to the initial value of the accumulator 311 to assist the signal CDR_CLK in leaving the detection dead zone DZ.

It should be noted that the initial signal PI can affect the phase and/or frequency of the signal CDR_CLK, and is used to pre-establish a default phase shift or a default frequency difference of the signal CDR_CLK with respect to the signal Din before the signal Din and the signal CDR_CLK are compared for the first time. After the default phase shift or the default frequency difference is generated, the signal CDR_CLK can be quickly removed from the detection dead zone DZ through the continuous operation between the phase detector 11, the digital loop filter 12 and the phase interpolator 13, and the signal Din and the signal CDR_CLK can be locked in the correct phase relationship.

It should be noted that the digital loop filter 32 illustrated in the exemplary embodiment of FIG. 3 is merely an example and is not intended to limit the disclosure. In another exemplary embodiment, the number of amplifiers and the number of accumulators in the digital loop filter 32 as well as the coupling relationship between the various electronic components can be adjusted according to actual requirements. In addition, other types of electronic components may be included in the digital loop filter 32 to provide other additional functions, the disclosure provides no limitation thereto. Alternatively, in an exemplary embodiment, the default value may also be stored or burned in other types of electronic components in the clock and data recovery circuit (or digital loop filter), as long as it can be used to generate the default phase shift or the default frequency difference between the signal Din and the signal CDR_CLK in FIG. 1.

In an exemplary embodiment, the clock and data recovery circuit 10 of FIG. 1 may be disposed in a memory storage device or a memory control circuit unit. Alternatively, in an exemplary embodiment, the clock and data recovery circuit 10 of FIG. 1 may also be disposed in any type of electronic device, the disclosure provides no limitation thereto.

In general, a memory storage device (also referred to as a memory storage system) includes a rewritable non-volatile memory module and a controller (also referred to as a control circuit). Typically, the memory storage device is used together with a host system to enable the host system to write data to or read data from the memory storage device.

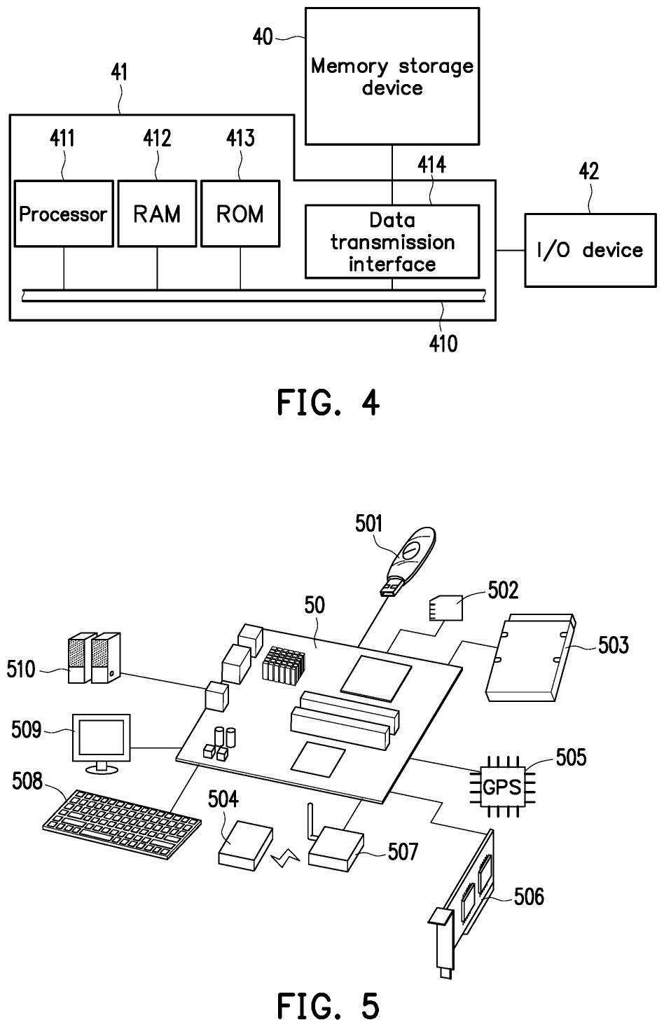

FIG. 4 is a schematic diagram of a host system, a memory storage device, and an input/output (I/O) device according to an exemplary embodiment of the disclosure. FIG. 5 is a schematic diagram of a host system, a memory storage device, and an I/O device according to another exemplary embodiment of the disclosure.

Referring to FIG. 4 and FIG. 5, the host system 41 generally includes a processor 411, a random access memory (RAM) 412, a read only memory (ROM) 413, and a data transmission interface 414. The processor 411, the random access memory 412, the read only memory 413, and the data transmission interface 414 are all coupled to a system bus 410.

In the exemplary embodiment, the host system 41 is coupled to the memory storage device 40 through the data transmission interface 414. For example, the host system 41 can store data to or read data from the memory storage device 40 through the data transmission interface 414. In addition, the host system 41 is coupled to the I/O device 42 through the system bus 410. For example, the host system 41 can transmit output signals to or receive input signals from the I/O device 42 through the system bus 410.

In the exemplary embodiment, the processor 411, the random access memory 412, the read only memory 413, and the data transmission interface 414 may be disposed on the main board 50 of the host system 41. The number of data transmission interfaces 414 can be one or more. The main board 50 can be coupled to the memory storage device 40 in a wired or wireless manner through the data transmission interface 414. The memory storage device 40 can be, for example, a flash drive 501, a memory card 502, a solid state drive (SSD) 503, or a wireless memory storage device 504. The wireless memory storage device 504 may be, for example, a memory storage device based on various wireless communication technologies, such as a near field communication (NFC) memory storage device, a wireless fidelity (WiFi) memory storage device, a Bluetooth memory storage device, or a BLE (Bluetooth low energy) memory storage device (e.g., iBeacon). Further, the main board 50 may also be coupled to various I/O devices, such as a GPS (Global Positioning System) module 505, a network interface card 506, a wireless transmission device 507, a keyboard 508, a monitor 509 and/or a speaker 510 through the system bus 410. For example, in an exemplary embodiment, the main board 50 can access the wireless memory storage device 504 through the wireless transmission device 507.

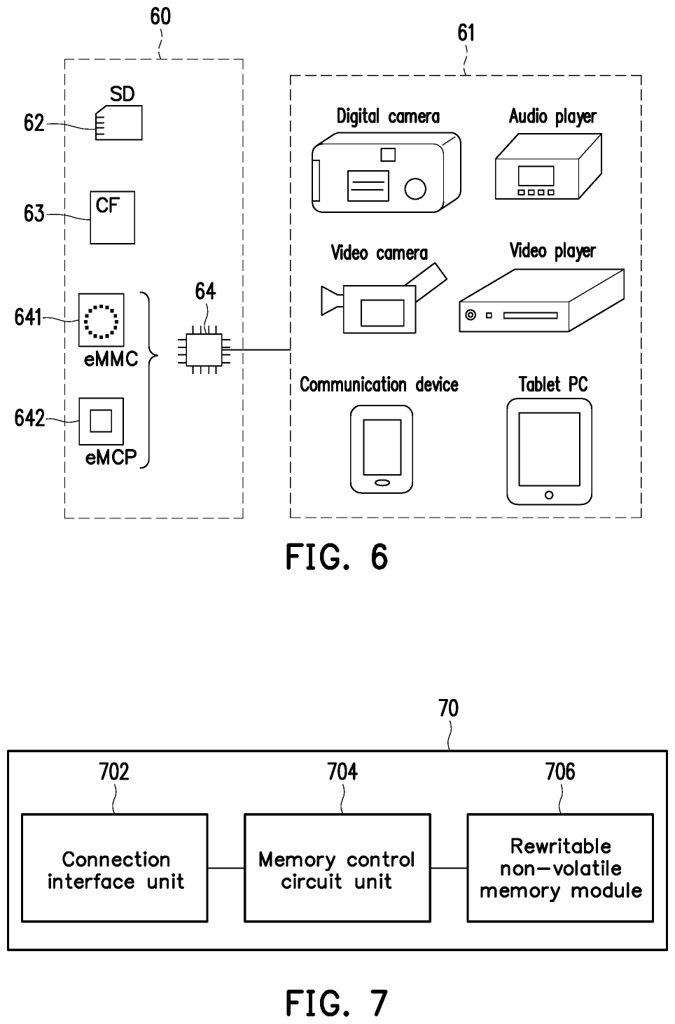

In an exemplary embodiment, the host system referred to is any system that can substantially cooperate with the memory storage device to store data. In the above exemplary embodiment, although the host system is exemplified as a computer system, FIG. 6 is a schematic diagram of a host system and a memory storage device according to another exemplary embodiment of the disclosure. Referring to FIG. 6, in another exemplary embodiment, the host system 61 can also be a digital camera, a video camera, a communication device, an audio player, a video player, or a tablet computer, and the memory storage device 60 can be various non-volatile memory storage devices used such as a secure digital (SD) card 62, a compact flash (CF) card 63, or an embedded storage device 64. The embedded storage device 64 includes various types of embedded storage devices that directly couple the memory module on the substrate of the host system such as an embedded multimedia card (eMMC) 641 and/or an embedded multi-chip package (eMCP) storage device 642 and the like.

FIG. 7 is a schematic block diagram of a memory storage device according to an exemplary embodiment of the disclosure. Referring to FIG. 7, the memory storage device 70 includes a connection interface unit 702, a memory control circuit unit 704, and a rewritable non-volatile memory module 706.

The connection interface unit 702 is configured to couple the memory storage device 70 to the host system 61. The memory storage device 70 can communicate with the host system 61 through the connection interface unit 702. In the exemplary embodiment, the connection interface unit 702 is compatible with a SATA (Serial Advanced Technology Attachment) standard. Nevertheless, it should be understood that the disclosure is not limited thereto. The connection interface unit 702 may also be compatible with a PATA (Parallel Advanced Technology Attachment) standard, an IEEE (Institute of Electrical and Electronic Engineers) 1394 standard, a PCI Express (Peripheral Component Interconnect Express) interface standard, a USB (Universal Serial Bus) standard, a SD interface standard, a UHS-I (Ultra High Speed-I) interface standard, a UHS-II (Ultra High Speed-II) interface standard, a MS (Memory Stick) interface standard, a MCP interface standard, a MMC interface standard, an eMMC interface standard, a UFS (Universal Flash Storage) interface standard, an eMCP interface standard, a CF interface standard, an IDE (Integrated Device Electronics) interface standard or other suitable standards. The connection interface unit 702 and the memory control circuit unit 704 may be packaged into one chip, or the connection interface unit 702 is distributed outside of a chip containing the memory control circuit unit 704.

The memory control circuit unit 704 is configured to execute a plurality of logic gates or control commands implemented in the form of hardware or firmware, and perform operations, such as writing, reading or erasing data in the rewritable non-volatile memory module 706 according to the commands of the host system 61.

The rewritable non-volatile memory module 706 is coupled to the memory control circuit unit 704 and configured to store data written from the host system 61. The rewritable non-volatile memory module 706 may be a SLC (Single Level Cell) NAND flash memory module (i.e., a flash memory module capable of storing one bit in one memory cell), a MLC (Multi Level Cell) NAND flash memory module (i.e., a flash memory module capable of storing two bits in one memory cell), a TLC (Triple Level Cell) NAND flash memory module (i.e., a flash memory module capable of storing three bits in one memory cell), a QLC (Quad Level Cell) NAND flash memory module (i.e., a flash memory module capable of storing four bits in one memory cell), other flash memory modules or any memory module having the same features.

Each of the memory cells in the rewritable non-volatile memory modules 706 stores one or more bits in response to a variation in voltage (hereinafter also referred to as a threshold voltage). Specifically, there is a charge trapping layer between the control gate and the channel of each memory cell. By applying a write voltage to the control gate, the amount of electrons in the charge trapping layer can be changed, thereby changing the threshold voltage of the memory cell. This operation of changing the threshold voltage of the memory cell is also referred to as “writing data to the memory cell” or “programming memory cell”. Each of the memory cells in the rewritable non-volatile memory modules 1006 has a plurality of storage states along with variation of the threshold voltage. By applying the read voltage, it can be determined which storage state that a memory cell belongs to, thereby obtaining one or more bits stored in the memory cell.

In the exemplary embodiment, the memory cells of the rewritable non-volatile memory module 706 may constitute a plurality of physical programming units, and the physical programming units may constitute a plurality of physical erasing units. Specifically, the memory cells on the same word line may form one or more physical programming units. If each memory cell can store two or more bits, the physical programming units on the same word line can be at least classified into a lower physical programming unit and an upper physical programming units. For example, a least significant bit (LSB) of a memory cell belongs to a lower physical programming unit, and a most significant bit (MSB) of a memory cell belongs to an upper physical programming unit. In general, in the MLC NAND flash memory, the write speed of the lower physical programming unit is greater than the write speed of the upper physical programming unit, and/or the reliability of the lower physical programming unit is higher than the reliability of the upper physical programming unit.

In the exemplary embodiment, the physical programming unit is the minimum unit that is programmed. That is, the physical programming unit is the minimum unit for writing data. For example, the physical programming unit may be a physical page or a physical sector. If the physical programming unit is a physical page, the physical programming units may include a data bit area and a redundancy bit area. The data bit area includes a plurality of physical sectors for storing user data, and the redundant bit area is used to store system data (for example, management data such as error-correction codes). In this exemplary embodiment, the data bit area includes 32 physical sectors, and one physical sector has a size of 512B (byte). However, in other exemplary embodiments, the data bit area may also contain 8, 16, or a greater or lesser number of physical sectors, and the size of each of the physical sectors may also be larger or smaller. On the other hand, the physical erasing unit is the minimum unit for erasing. That is, each physical erasing unit contains the smallest number of erased memory cells. For example, the physical erasing unit is a physical block.

In an exemplary embodiment, the rewritable non-volatile memory module 706 of FIG. 7 is also referred to as a flash memory module. In an exemplary embodiment, the memory control circuit unit 704 of FIG. 7 is also referred to as a flash memory controller for controlling a flash memory module. In an exemplary embodiment, the clock and data recovery circuit 10 of FIG. 1 may be disposed in the connection interface unit 702 or the memory control circuit unit 704 of FIG. 10. For example, the clock and data recovery circuit 10 can be used to process data signals from the host system.

In summary, according to the exemplary embodiment of the disclosure, a default value may be pre-stored in the clock and data recovery circuit. The default value is used to establish a default phase shift or a default frequency difference of the clock signal with respect to the data signal before the data signal and the clock signal are compared. In some cases, if the phase (or sampling point) of the clock signal is in the detection dead zone, the default phase shift or default frequency difference helps to quickly drive the clock signal away from the detection dead zone, thereby effectively increasing the operation efficiency of the clock and data recovery circuit.

Although the invention has been disclosed by the above embodiments, the embodiments are not intended to limit the invention. It will be apparent to those skilled in the art that various modifications and variations can be made to the structure of the invention without departing from the scope or spirit of the disclosure. Therefore, the protecting range of the invention falls in the appended claims.

What is claimed is:

1. A clock and data recovery circuit, comprising:
a phase detector, detecting a phase difference between a data signal and a clock signal;
a digital loop filter, coupled to the phase detector; and
a phase interpolator, coupled to the phase detector and the digital loop filter and configured for generating the clock signal according to an output of the digital loop filter,
wherein the digital loop filter is configured to automatically operate according to a default value stored in the digital loop filter under an initial state to establish a default phase shift or a default frequency difference of the clock signal with respect to the data signal before the data signal is compared with the clock signal.

2. The clock and data recovery circuit according to claim 1, wherein the default value is not provided by the phase detector.

3. The clock and data recovery circuit according to claim 1, wherein the default value is independent of the phase difference.

4. The clock and data recovery circuit according to claim 1, wherein the digital loop filter comprises:
at least one amplifier, coupled to an output terminal of the phase detector; and
at least one accumulator, coupled to an output terminal of the at least one amplifier and an input terminal of the phase interpolator,
wherein the default value is burned in the at least one accumulator.

5. The clock and data recovery circuit according to claim 4, wherein the at least one amplifier comprises a first amplifier and a second amplifier, the at least one accumulator comprising a first accumulator and a second accumulator, an input terminal of the first amplifier and an input terminal of the second amplifier are coupled to the output terminal of the phase detector, and an input terminal of the first accumulator is coupled to an output terminal of the second amplifier, an input terminal of the second accumulator is coupled to an output terminal of the first amplifier and an output terminal of the first accumulator, and an output terminal of the second accumulator is coupled to the phase interpolator.

6. The clock and data recovery circuit according to claim 5, wherein the default value is burned in the first accumulator.

7. The clock and data recovery circuit according to claim 1, wherein the default value is an integer and the default value is not zero.

8. A memory storage device, comprising:
a connection interface unit, configured for coupling to a host system;
a rewritable non-volatile memory module;
a memory control circuit unit, coupled to the connection interface unit and the rewritable non-volatile memory module; and
a clock and data recovery circuit, disposed in at least one of the connection interface unit and the memory control circuit unit,
wherein the clock and data recovery circuit is configured to receive a data signal, generate a clock signal, and detect a phase difference between the data signal and the clock signal, and
the clock and data recovery circuit is further configured to automatically operate according to a default value stored in the clock and data recovery circuit under an initial state to establish a default phase shift or a default frequency difference of the clock signal with respect to the data signal before the data signal is compared with the clock signal.

9. The memory storage device according to claim 8, wherein the default value is not provided by a phase detector.

10. The memory storage device according to claim 8, wherein the default value is independent of the phase difference.

11. The memory storage device according to claim 8, wherein the clock and data recovery circuit comprises a phase detector, a digital loop filter and a phase interpolator, and the digital loop filter comprising:
at least one amplifier, coupled to an output terminal of the phase detector; and
at least one accumulator, coupled to an output terminal of the at least one amplifier and an input terminal of the phase interpolator,
wherein the default value is burned in the at least one accumulator.

12. The memory storage device according to claim 11, wherein the at least one amplifier comprises a first amplifier and a second amplifier, the at least one accumulator comprising a first accumulator and a second accumulator, an input terminal of the first amplifier and an input terminal of the second amplifier are coupled to the output terminal of the phase detector, and an input terminal of the first accumulator is coupled to an output terminal of the second amplifier, an input terminal of the second accumulator is coupled to an output terminal of the first amplifier and an output terminal of the first accumulator, and an output terminal of the second accumulator is coupled to the phase interpolator.

13. The memory storage device according to claim 12, wherein the default value is burned in the first accumulator.

14. The memory storage device according to claim 8, wherein the default value is an integer and the default value is not zero.

15. The memory storage device according to claim 8, wherein the clock and data recovery circuit comprises:
a phase detector, configured for detecting the phase difference between the data signal and the clock signal;
a digital loop filter, coupled to the phase detector; and
a phase interpolator, coupled to the phase detector and the digital loop filter and configured for generating the clock signal according to an output of the digital loop filter,
wherein the digital loop filter is configured to automatically operate according to the default value stored in the digital loop filter under the initial state to establish the default phase shift or the default frequency difference of the clock signal with respect to the data signal before the data signal is compared with the clock signal.

16. A flash memory controller, configured for controlling a rewritable non-volatile memory module, and the flash memory controller comprising:
a clock and data recovery circuit, configured for receiving a data signal, generating a clock signal, and detecting a phase difference between the data signal and the clock signal, and
wherein the clock and data recovery circuit is further configured to automatically operate according to a default value stored in the clock and data recovery circuit under an initial state to establish a default phase shift or a default frequency difference of the clock signal with respect to the data signal before the data signal is compared with the clock signal.

17. The flash memory controller according to claim 16, wherein the default value is not provided by a phase detector.

18. The flash memory controller according to claim 16, wherein the default value is independent of the phase difference.

19. The flash memory controller according to claim 16, wherein the clock and data recovery circuit comprises a phase detector, a digital loop filter and a phase interpolator, and the digital loop filter comprises:
at least one amplifier, coupled to an output terminal of the phase detector; and
at least one accumulator, coupled to an output terminal of the at least one amplifier and an input terminal of the phase interpolator,
wherein the default value is burned in the at least one accumulator.

20. The flash memory controller according to claim 19, wherein the at least one amplifier comprises a first amplifier and a second amplifier, the at least one accumulator comprising a first accumulator and a second accumulator, an input terminal of the first amplifier and an input terminal of the second amplifier are coupled to the output terminal of the phase detector, and an input terminal of the first accumulator is coupled to an output terminal of the second amplifier, an input terminal of the second accumulator is coupled to an output terminal of the first amplifier and an output terminal of the first accumulator, and an output terminal of the second accumulator is coupled to the phase interpolator.

21. The flash memory controller according to claim 20, wherein the default value is burned in the first accumulator.

22. The flash memory controller according to claim 16, wherein the default value is an integer and the default value is not zero.

23. The flash memory controller according to claim 16, wherein the clock and data recovery circuit comprises:
a phase detector, configured for detecting the phase difference between the data signal and the clock signal;
a digital loop filter, coupled to the phase detector; and
a phase interpolator, coupled to the phase detector and the digital loop filter and configured for generating the clock signal according to an output of the digital loop filter,
wherein the digital loop filter is configured to automatically operate according to the default value stored in the digital loop filter under the initial state to establish the default phase shift or the default frequency difference of the clock signal with respect to the data signal before the data signal is compared with the clock signal.
